(19) United States
(12) Patent Application Publication
(10) Pub. No.: US 2006/0068098 A1
(43) Pub. Date: Mar. 30, 2006

(54) Deposition of ruthenium metal layers in a thermal chemical vapor deposition process

(75) Inventors: Hideaki Yamasaki, Kofu-City (JP); Yumiko Kawano, Kofu-City (JP); Gert J. Leusink, Saltpoint, NY (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/949,803

(22) Filed: Sep. 27, 2004

(51) Int. Cl. C23C 16/00

(52) U.S. Cl. 427/248.1

(57) ABSTRACT

A method for depositing a Ru metal layer on a substrate is presented. The method includes providing a substrate in a process chamber, introducing a process gas in the process chamber in which the process gas comprises a carrier gas, a ruthenium-carbonyl precursor, and hydrogen. The method further includes depositing a Ru metal layer on the substrate by a thermal chemical vapor deposition process. In one embodiment of the invention, the ruthenium-carbonyl precursor can contain Ru₃(CO)₁₂. and the Ru metal layer can be deposited at a substrate temperature resulting in the Ru metal layer having predominantly Ru(002) crystallographic orientation.

### FIELD OF THE INVENTION

The present invention relates to semiconductor processing, and more particularly, to a method for depositing ruthenium metal layers in a thermal chemical vapor deposition process.

### BACKGROUND OF THE INVENTION

The introduction of copper (Cu) metal into multilayer metallization schemes for manufacturing integrated circuits (ICs), can necessitate the use of diffusion barriers/liners to promote adhesion and growth of the Cu layers, and to prevent diffusion of Cu into the dielectric materials. Barriers/liners that are deposited onto dielectric materials can include refractive materials such as ruthenium (Ru), rhenium (Re), tungsten (W), molybdenum (Mo), and tantalum (Ta), that are non-reactive and immiscible with Cu and can offer low electrical resistivity. Current integration schemes that integrate Cu metallization and dielectric materials can require barrier/liner deposition processes at substrate temperatures between about 400° C. and about 500° C., or lower.

Thermal chemical vapor deposition (TCVD) is a particularly attractive method for forming thin layers on substrates in the semiconductor industry, because the method has the ability to readily control the composition of the thin layers and to form a thin layer without contamination of, or damage to, the substrate. TCVD can also be used to deposit the desired thin layer into holes, trenches, and other stepped structures. In situations where conformal thin layer deposition is required, TCVD can be a preferred method of deposition, since evaporation and sputtering techniques cannot be used to form a conformal thin layer.

TCVD processes require suitable precursors that are sufficiently volatile to permit a rapid transport of their vapors into the TCVD process chamber to deposit layers at sufficiently high deposition rates for device manufacturing. The precursors should be relatively stable and decompose cleanly on the substrate in the process chamber to deposit a high-purity layer at the desired substrate temperature. In the case of a metal layer, control over the crystallographic orientation of deposited metal layer can be required, since the stress, the morphology, and electrical resistivity of the metal layer, can be a function of the crystallographic orientation.

### SUMMARY OF THE INVENTION

Embodiments of the present invention, as broadly described herein, provide for a method of depositing a thin Ru metal layer on a substrate in a thermal chemical vapor deposition process.

In one embodiment of the invention, the method comprises providing a substrate in a process chamber, introducing a process gas in the process chamber in which the process gas comprises a carrier gas, a ruthenium-carbonyl precursor, and hydrogen gas. The method further comprises depositing a Ru metal layer on the substrate by a thermal chemical vapor deposition process. In one embodiment of the invention, the ruthenium-carbonyl precursor can contain Ru₃(CO)₁₂.

In one embodiment of the invention, the deposition occurs at a substrate temperature resulting in the Ru metal layer having predominantly Ru(002) crystallographic orientation.

In another embodiment of the invention, a method is provided for depositing a Ru metal layer on a patterned substrate. The method includes providing a patterned substrate in a process chamber, the patterned substrate containing one or more vias, trenches or combinations thereof, introducing a process gas in the process chamber, the process gas comprising a carrier gas, a ruthenium-carbonyl precursor, and hydrogen gas, and depositing a Ru metal layer on the patterned substrate by a thermal chemical vapor deposition process.

According to one embodiment of the invention, the patterned substrate can contain a W barrier layer and the Ru metal layer can be deposited on the W barrier layer.

Other aspects of the invention will be made apparent from the description that follows and from the drawings appended hereto.

### BRIEF DESCRIPTION OF THE DRAWINGS

Embodiments of the present invention will be described, by way of example, with reference to the accompanying drawings in which:

FIG. 1 is a simplified block-diagram of a processing system for depositing a Ru metal layer on a substrate, according to an embodiment of the invention;

FIGS. 2A-2C schematically show a substrates containing thin Ru metal layers deposited thereon, according to embodiments of the invention; and

FIG. 3 shows a flowchart for depositing a metal layer, according to an embodiment of the invention.

### DETAILED DESCRIPTION OF SEVERAL EMBODIMENTS

Various embodiments of the present invention are described below. Where appropriate, like reference numerals are used to refer to like features. The embodiments presented herein are intended to be merely exemplary of the wide variety of embodiments contemplated within the scope of the present invention, as would be appreciated by those skilled in the art. Accordingly, the present invention is not limited solely to the embodiments presented, but also encompasses any and all variations that would be appreciated by those skilled in the art.

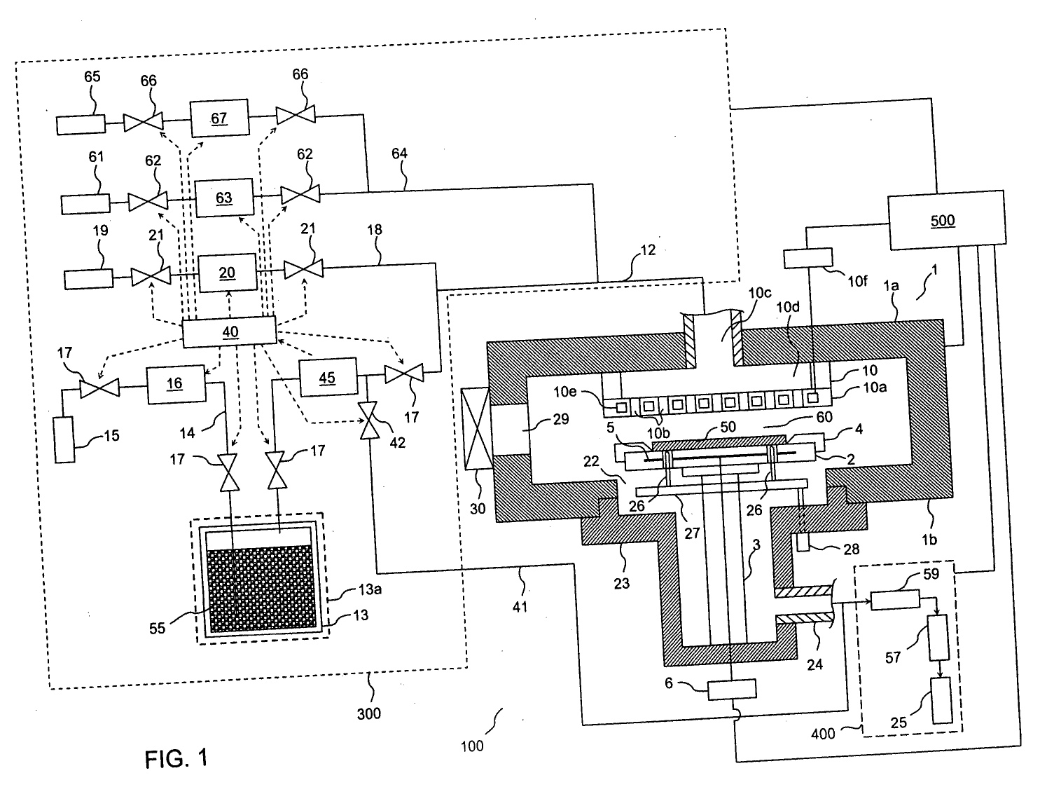

FIG. 1 is a simplified block-diagram of a processing system for depositing a Ru metal layer on a substrate according to an embodiment of the invention. The processing system 100 comprises a process chamber 1 that includes an upper chamber section 1a, a lower chamber section 1b, and an exhaust chamber 23. A circular opening 22 is formed in the middle of the lower chamber section 1b, where the bottom section 1bconnects to the exhaust chamber 23.

Provided inside the process chamber 1 is a substrate holder 2 for horizontally holding a substrate (wafer) 50 to be processed. The substrate holder 2 is supported by a cylindrical support member 3, which extends upward from the center of the lower part of the exhaust chamber 23. A guide ring 4 for positioning the substrate 50 on the substrate holder 2 is provided on the edge of the substrate holder 2. Furthermore, the substrate holder 2 contains a heater 5 that is controlled by power source 6, and is used for heating the substrate 50. The heater 5 may comprise a resistive heater or any heater suitable for such purposes, such as, for example, a lamp heater.

During processing, the heated substrate 50 can thermally decompose a ruthenium-carbonyl precursor 55 and enable deposition of a Ru metal layer on the substrate 50. According to one embodiment of the present invention, the ruthenium-carbonyl precursor 55 may comprise Ru₃(CO)₁₂. As will be appreciated by those skilled in the art, other ruthenium-carbonyl precursors can be used without departing from the scope of the present invention.

The substrate holder 2 is heated to a pre-determined temperature that is suitable for depositing the desired Ru metal layer onto the substrate 50. A heater (not shown) is embedded in the walls of the process chamber 1 to heat the chamber walls to a pre-determined temperature. The heater 5 can maintain the temperature of the walls of the process chamber 1 from about 40° C. to about 80° C.

As shown in FIG. 1, the upper chamber section 1a of the process chamber 1 includes a showerhead 10 with a showerhead plate 10a disposed at the bottom of showerhead 10. The showerhead plate 10a contains multiple gas delivery holes 10b for delivering a process gas comprising the ruthenium-carbonyl precursor 55 into a processing zone 60 located above the substrate 50.

The upper chamber section 1b includes an opening 10c for introducing a process gas from a gas line 12 into a gas distribution compartment 10d. To prevent the decomposition of the ruthenium-carbonyl precursor 55 inside the showerhead 10, concentric coolant flow channels 10e are provided for controlling the temperature of the showerhead 10. A coolant fluid, such as, for example, water, can be supplied to the coolant flow channels 10e from a coolant fluid source 10f in order to control the temperature of the showerhead 10 from about 20° C. to about 100° C.

A precursor delivery system 300 is coupled to the process chamber 1 via the gas line 12. The precursor delivery system 300 comprises, inter alia, a precursor container 13, a precursor heater 13a, a gas source 15, mass flow controllers (MFCs) 16, 20, a gas flow sensor, and a gas controller 40. The precursor container 13 contains a solid ruthenium-carbonyl precursor 55, and the precursor heater 13a is provided for heating the precursor container 13 to maintain the ruthenium-carbonyl precursor 55 at a temperature that produces a desired vapor pressure of the ruthenium-carbonyl precursor 55.

The ruthenium-carbonyl precursor 55 can be delivered to the process chamber 1 using a carrier gas to enhance the delivery of the precursor to the process chamber 1. A gas line 14 can provide a carrier gas from the gas source 15 to the precursor container 13 and the mass flow controller (MFC) 16 can be used to control the carrier gas flow. The carrier gas may be introduced into the lower part of precursor container 13 so as to percolate through the solid ruthenium-carbonyl precursor 55. Alternately, the carrier gas may be introduced into the precursor source 13 and distributed across the top of the solid metal-carbonyl precursor 55.

A sensor 45 is provided for measuring the total gas flow from the precursor container 13. The sensor 45 can, for example, comprise a MFC, and the amount of ruthenium-carbonyl precursor 55 delivered to the process chamber 1, can be determined using sensor 45 and mass flow controller 16. Alternately, the sensor 45 can comprise a light absorption sensor to measure the concentration of the ruthenium-carbonyl precursor in the gas flow to the process chamber 1.

A bypass line 41 is located downstream from the sensor 45 and connects the gas line 12 to an exhaust line 24. The bypass line 41 is provided for evacuating the gas line 12 and for stabilizing the supply of the ruthenium-carbonyl precursor 55 to the process chamber 1. In addition, a valve 42, located downstream from the branching of the gas line 12, is provided on the bypass line 41.

Heaters (not shown) are provided to independently heat the gas lines 12, 14, and 41. As such, the temperatures of the gas lines can be controlled to avoid condensation of the ruthenium-carbonyl precursor 55 in the gas lines 12, 14, 41. The temperature of the gas lines 12, 14, 41 can be controlled from about 20° C. to about 100° C., although in some cases, controlling the temperature from about 25° C. to about 60° C. may be sufficient.

Dilution gases can be supplied from a gas source 19 to the gas line 12 using a gas line 18. The dilution gases can be used to dilute the process gas or to adjust the process gas partial pressure(s). The gas line 18 contains a mass flow controller (MFC 20) and valves 21. The MFCs 16 and 20, and the valves 17, 21, and 42 are controlled by the controller 40, which controls the supply, shutoff, and the flow of a carrier gas, the metal-carbonyl precursor gas, and a dilution gas. The sensor 45 is also connected to the controller 40 and, based on output of the sensor 45, the controller 40 can control the carrier gas flow through the mass flow controller 16 to obtain the desired ruthenium-carbonyl precursor flow rate to the process chamber 1.

A reducing gas can be supplied from a gas source 61 to the process chamber 1 using a gas line 64, a MFC 63, and valves 62. In one embodiment of the present invention, the reducing gas can be hydrogen (H₂). A purge gas can be supplied from a gas source 65 to process chamber 1 using the gas line 64, a MFC 67, and valves 66. The controller 40 can control the supply, shutoff, and the flow of the reducing gas and the purge gas.

The exhaust line 24 connects the exhaust chamber 23 to a vacuum pumping system 400. The vacuum pumping system 400 comprises an automatic pressure controller (APC) 59, a trap 57, and a vacuum pump 25. The vacuum pump 25 is used to evacuate the process chamber 1 to a desired degree of vacuum and to remove gaseous species from the process chamber 1 during processing. The APC 59 and the trap 57 can be used in series with the vacuum pump 25. The vacuum pump 25 may comprise a turbo-molecular pump (TMP) capable of pumping speeds up to 5000 liters per second (and greater). Alternately, the vacuum pump 25 may comprise a dry pump.

During processing, the process gas can be introduced into the process chamber 1 and the chamber pressure may be adjusted by the APC 59. The APC 59 can comprise a butterfly-type valve or any suitable valve, such as, for example, a gate valve. The trap 57 can collect unreacted precursor material and by-products from the process chamber 1.

Focusing on the process chamber 1, three substrate lift pins 26 (only two are shown) are provided for holding, raising, and lowering the substrate 50. The substrate lift pins 26 are affixed to a plate 27, and can be lowered to a position below the upper surface of the substrate holder 2. A drive mechanism 28 utilizing, for example, an air cylinder, may be configured to raise and lower the plate 27. The substrate 50 can be transferred into and out of the process chamber 1 through a gate valve 30 and a chamber feed-through passage 29 via a robotic transfer system (not shown) and received by the substrate lift pins 26. Once the substrate 50 is received from the transfer system, it can be lowered to the upper surface of the substrate holder 2 by lowering the substrate lift pins 26.

The processing system 100 may be controlled by a processing system controller 500. In particular, a processing system controller 500 comprises a microprocessor, a memory, and a digital I/O port capable of generating control voltages sufficient to communicate and activate inputs of the processing system 100 as well as monitor outputs from the processing system 100. Moreover, the processing system controller 500 may be coupled to, and exchanges information with, the process chamber 1, the precursor delivery system 300 that includes the controller 40 and the precursor heater 13a, the vacuum pumping system 400, the power source 6, and the coolant fluid source 10f.

In the vacuum pumping system 400, the processing system controller 500 is coupled to, and exchanges information with, the automatic pressure controller (APC) 59 for controlling the pressure in the process chamber 1. A program stored in the memory is utilized to control the aforementioned components of the processing system 100 according to a stored process recipe. One example of processing system controller 500 is a DELL PRECISION WORKSTATION 610™, available from Dell Corporation, Dallas, Tex.

A processing system for forming Ru metal layers can comprise a single wafer process chamber 1 as is schematically shown and described in FIG. 1. Alternately, the processing system can comprise a batch type process chamber capable of processing multiple substrates (wafers) 50 simultaneously. In addition to semiconductor substrates 50, (e.g., Si wafers), the substrates can, for example, comprise LCD substrates, glass substrates, or compound semiconductor substrates. The process chamber 1 can, for example, process substrates of any size, such as 200 mm substrates, 300 mm substrates, or even larger substrates. It will be apparent to those skilled in the art that modifications may be made to the processing system 100 chosen for illustration in FIG. 1 without departing from the spirit and scope of the present invention.

Thermal decomposition of ruthenium-carbonyl precursor 55 and subsequent Ru metal deposition on the substrate 50, is thought to proceed predominantly by CO elimination and desorption of CO by-products from the substrate 50. Incorporation of CO by-products into the Ru metal layer can result from incomplete decomposition of the ruthenium-carbonyl precursor 55, incomplete removal of the CO by-products from the Ru metal layer, and re-adsorption of CO by-products from the processing zone 60 onto the Ru metal layer. Lowering of the process chamber pressure results in a shorter residence of gaseous species (e.g., ruthenium-carbonyl precursor, reaction by-products, carrier gas, and dilution gas) in the processing zone 60 above the substrate 50, which in turn, can result in lower CO impurity levels in a Ru metal layer deposited on the substrate 50.

Embodiments of the invention are well suited for depositing thin Ru metal layers on un-patterned substrates and on patterned substrates containing vias (holes), trenches, and other structures. In situations where conformal thin Ru metal layer deposition is required over high aspect ratio structures, the TCVD process described in embodiments of the invention can be a preferred method of deposition.

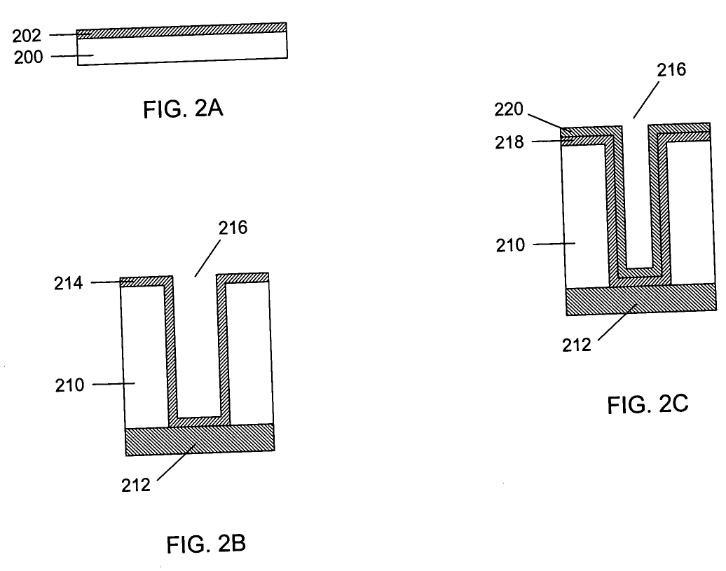

FIG. 2A schematically depicts a substrate 200 containing a thin Ru metal layer 202 deposited thereon, in accordance with an embodiment of the present invention. According to one embodiment, the thickness of the metal layer 202 can be less than about 300 Angstroms (Å). Alternately, other embodiments contemplate the thickness to be less than about 200 Å or even less than about 100 Å.

FIG. 2B schematically shows a patterned substrate 210 containing a thin Ru metal layer 214 deposited thereon according to an embodiment of the invention. The patterned substrate 210 also contains an opening 216 that can, for example, be a via, a trench, or another structure. The thin Ru metal layer 214 can, for example, be a barrier layer between the patterned substrate 210, the first metal layer 212, and a second metal layer to be deposited in the opening 216. In another example, the thin Ru metal layer 214 can be a seed layer for subsequent deposition of Cu in the opening 216 by a plating process. In yet another example, schematically shown in FIG. 2C, the thin Ru metal layer 220 (seed layer) can be deposited onto a barrier layer 218 containing another material (e.g., W), and subsequently Cu deposited in the opening 216.

The current inventors have realized that utilizing a process gas containing a ruthenium-carbonyl precursor, a carrier gas, and hydrogen gas, can be used to deposit a smooth Ru metal layer on a substrate in a TCVD process. In addition, the hydrogen gas increases the amount of the Ru(002) crystallographic orientation in the deposited Ru metal layer relative to the Ru(101) crystallographic orientation.

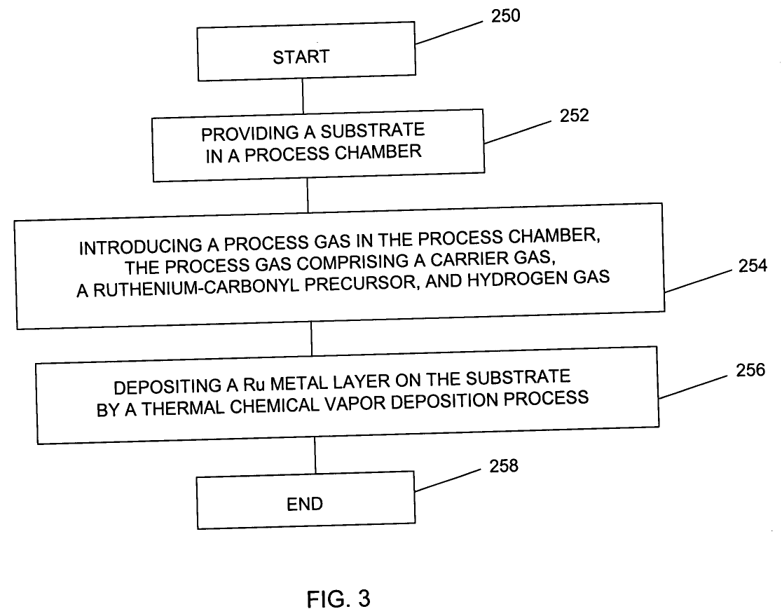

FIG. 3 depicts a flowchart for a process of depositing a Ru layer, in accordance with an embodiment of the present invention. In task 250, the process is started. In step 252, a substrate is provided in a process chamber.

In task 254, a process gas is introduced in the process chamber, where the process gas includes a carrier gas, a ruthenium-carbonyl precursor, and hydrogen gas. According to one embodiment of the invention, the ruthenium-containing precursor can contain Ru₃(CO)₁₂.

In task 256, a Ru metal layer is deposited on the substrate by a thermal chemical vapor deposition process. According to one embodiment of the invention, the depositing is conducted at a substrate temperature resulting in the Ru metal layer having predominantly Ru(002) crystallographic orientation.

As indicated in FIG. 3, after the deposition of the Ru metal layer the process terminates in task 258.

The process parameter space for the TCVD process utilizes a process chamber pressure between about 20 mTorr and about 500 mTorr. Alternately, the process chamber pressure can be between about 100 mTorr and about 300 mTorr, and can be about 170 mTorr. The carrier gas flow rate can be between about 100 standard cubic centimeters per minute (sccm) and about 5,000 sccm. Alternately, the carrier gas flow rate can be between about 500 sccm and about 2,000 sccm. The hydrogen gas flow rate can be between about 10 sccm and about 1000 sccm. Alternately, the hydrogen gas flow rate can be between about 100 sccm and about 500 sccm. The carrier gas can contain an inert gas selected from Ar, He, Ne, Kr, Xe, and N₂ or any combination of two or more thereof. The substrate temperature can be between about 300° C. and about 600° C. Alternately, the substrate temperature can be between about 350° C. and about 450° C.

### EXAMPLES

By way of example, Ru metal layers were deposited onto Si substrates using a Ru₃(CO)₁₂ precursor, Ar carrier gas, and H₂ gas, in a TCVD process at substrate temperatures of 300° C. and 400° C. For comparison, Ru metal layers were deposited without the use of H₂ gas.

The crystallographic orientations of the deposited Ru metal films were measured using X-ray diffraction (XRD), and for the process conditions studied, all the diffraction lines could be assigned to Ru metal and the underlying Si substrate. In particular, XRD intensities at 42.3 degrees corresponding to the Ru(002) crystallographic orientation, and XRD intensities at 44.1 degrees corresponding to the Ru(101) crystallographic orientation were measured. For a hexagonal close-packed (hcp) structure such as Ru metal, the most thermodynamically stable face is the (002).

In a first example, the Ru metal layers were deposited at a process chamber pressure of 170 mTorr, an Ar carrier gas flow rate of 1,000 sccm, and a H₂ gas flow rate of 200 sccm. The temperature of the precursor container was 40° C. A Ru metal layer with a thickness of about 420 Å was deposited at a substrate temperature of 400° C. had an electrical resistivity of 13.9 μohm-cm and a Ru(002)/Ru(101) XRD ratio of 80.33. This electrical resistivity value, when compared to the bulk resistivity of 7.1 μohm-cm, is reasonable for integration of Ru metal layers into semiconductor devices. For comparison, a Ru metal layer with a thickness of about 470 Å was deposited at a substrate temperature of 300° C. and had an electrical resistivity of 182 μohm-cm. The measured Ru(002)/Ru(101) XRD ratio was 2.59.

In a second example, the Ru metal layers were deposited at a process chamber pressure of 140 mTorr and an Ar carrier gas flow rate of 1,000 sccm. No H₂ gas was used. The 451 Å thick Ru metal layer deposited at 400° C. had an electrical resistivity of 14.2 μohm-cm and a Ru(002)/Ru(101) XRD ratio of 21.21. For comparison, a 445 Å thick Ru metal layer was deposited at a substrate temperature of 300° C. and had an electrical resistivity of 173 μohm-cm. The measured Ru(002)/Ru(101) XRD ratio was 2.78.

In summary, for a substrate temperature above about 300° C., the addition of a H₂ gas to the process gas containing the Ru₃(CO)₁₂ precursor and Ar carrier gas, resulted in a significant increase in the Ru(002) crystallographic orientation relative to the Ru(101) orientation. Hence, the addition of H₂ gas to the process gas allows deposition of a thin Ru metal layer having predominantly Ru(002) crystallographic orientation. In particular, according to one embodiment of the invention, the Ru metal layer was deposited at a substrate temperature resulting in the Ru metal layer having a Ru(002)/Ru(101) XRD ratio greater than about 3.

According to yet another embodiment of the present invention, the Ru metal layer was deposited at a substrate temperature resulting in the Ru metal layer having a Ru(002)/Ru(101) XRD ratio greater than about 20. Furthermore, the addition of H₂ gas to the process gas resulted in deposition of thin Ru metal films with improved surface morphology, in particular, smooth Ru metal films with low surface roughness.

In another example, a Ru/W/Si film structure was formed. As depicted in FIG. 2C, a Ru/W layer can be used as a seed/barrier layer for Cu metallization schemes. First, a thin W nucleation layer was deposited onto the Si substrate. The W nucleation layer was deposited on the Si substrate using a process gas containing Ar carrier gas and W(CO)₆ precursor at a process chamber pressure of 500 mTorr, substrate temperature of 400° C., and an exposure time of 60 sec.

Next, a W barrier layer was deposited onto the W nucleation layer using a process gas containing Ar carrier gas, W(CO)₆ precursor, and H₂ gas at a process chamber pressure of 60 mTorr. The Ar carrier gas flow rate was 50 sccm and the H₂ gas flow rate was 100 sccm. The temperature of the W(CO)₆ precursor container was 35° C.

Subsequently, a Ru metal layer (seed layer) was deposited onto the W barrier layer using a process gas containing Ar carrier gas, Ru₃(CO)₁₂, and H₂ gas at process chamber pressure of 170 mTorr and a substrate temperature of 400° C. The thickness of the Ru metal layer was about 250 Å and the temperature of the W(CO)₆ precursor container was 40° C.

The electrical resistivity of the Ru metal layer in the Ru/W/Si film structure was calculated to be about 50 μohm-cm by subtracting the measured electrical resistivity of the W/Si film structure from the Ru/W/Si film structure. For comparison, another Ru/W/Si film structure was prepared without using H₂ gas in the deposition of the Ru metal layer. The electrical resistivity of the Ru metal layer in the Ru/W/Si film structure was calculated to be about 132 μohm-cm.

In summary, the use of H₂ gas in the deposition of the Ru metal layer in the Ru/W/Si film structure, significantly reduced the electrical resistivity of the Ru/W/Si film structure.

It should be understood that various modifications and variations of the present invention may be employed in practicing the invention. It is therefore to be understood that, within the scope of the appended claims, the invention may be practiced otherwise than as specifically described herein.

What is claimed is:

1. A method of depositing a Ru metal layer on a substrate, the method comprising:
providing a substrate in a process chamber;
introducing a process gas in the process chamber, the process gas comprising a carrier gas, a ruthenium-carbonyl precursor, and hydrogen gas; and
depositing a Ru metal layer on the substrate by a thermal chemical vapor deposition process.

2. The method according to claim 1, wherein the depositing is conducted at a substrate temperature resulting in the Ru metal layer having predominantly Ru(002) crystallographic orientation.

3. The method according to claim 2, wherein the depositing is conducted at a substrate temperature resulting in the Ru metal layer having a Ru(002)/Ru(101) XRD ratio greater than about 3.

4. The method according to claim 2, wherein the depositing is conducted at a substrate temperature resulting in the Ru metal layer having a Ru(002)/Ru(101) XRD ratio greater than about 20.

5. The method according to claim 1, wherein a substrate temperature is between about 300° C. and about 600° C.

6. The method according to claim 1, wherein a substrate temperature is between about 350° C. and about 500° C.

7. The method according to claim 1, wherein the ruthenium-carbonyl precursor comprises Ru₃(CO)₁₂.

8. The method according to claim 1, wherein a carrier gas flow is between about 100 sccm and about 5,000 sccm.

9. The method according to claim 1, wherein a carrier gas flow is between about 500 sccm and about 2000 sccm.

10. The method according to claim 1, wherein the carrier gas comprises Ar, He, Ne, Kr, Xe, or N₂, or a combination of two or more thereof.

11. The method according to claim 1, wherein a hydrogen gas flow rate is between about 10 sccm and about 1000 sccm.

12. The method according to claim 1, wherein a hydrogen gas flow rate is between about 100 sccm and about 500 sccm.

13. The method according to claim 1, wherein the process gas further comprises a dilution gas.

14. The method according to claim 13, wherein the dilution gas comprises Ar, He, Ne, Kr, Xe, or N₂, or a combination of two or more thereof.

15. The method according to claim 1, wherein the substrate comprises at least one of a semiconductor substrate, a LCD substrate, a glass substrate, or a combination of two or more thereof.

16. The method according to claim 1, wherein a thickness of the Ru metal layer is less than about 300 Å.

17. The method according to claim 1, wherein a thickness of the Ru metal layer is less than about 200 Å.

18. The method according to claim 1, wherein a thickness of the Ru metal layer is less than about 100 Å.

19. A method of depositing a Ru metal layer on a patterned substrate, the method comprising:
providing a patterned substrate in a process chamber, the patterned substrate containing one or more vias, trenches or combinations thereof;
introducing a process gas in the process chamber, the process gas comprising a carrier gas, a ruthenium-carbonyl precursor, and hydrogen gas; and
depositing a Ru metal layer on the patterned substrate by a thermal chemical vapor deposition process.

20. The method according to claim 19, wherein the depositing is conducted at a substrate temperature resulting in the Ru metal layer having predominantly Ru(002) crystallographic orientation.

21. The method according to claim 19, wherein the depositing is conducted at a substrate temperature resulting in the Ru metal layer having a Ru(002)/Ru(101) XRD ratio greater than about 3.

22. The method according to claim 19, wherein the depositing is conducted at a substrate temperature resulting in the Ru metal layer having a Ru(002)/Ru(101) XRD ratio greater than about 20.

23. The method according to claim 19, wherein a substrate temperature is between about 300° C. and about 600° C.

24. The method according to claim 19, wherein a substrate temperature is between about 350° C. and about 500° C.

25. The method according to claim 19, wherein the ruthenium-carbonyl precursor comprises Ru₃(CO)₁₂.

26. The method according to claim 19, wherein a carrier gas flow is between about 100 sccm and about 5,000 sccm.

27. The method according to claim 19, wherein a carrier gas flow is between about 500 sccm and about 2000 sccm.

28. The method according to claim 1, wherein the carrier gas comprises Ar, He, Ne, Kr, Xe, or N₂, or a combination of two or more thereof.

29. The method according to claim 19, wherein a hydrogen gas flow rate is between about 10 sccm and about 1000 sccm.

30. The method according to claim 19, wherein a hydrogen gas flow rate is between about 100 sccm and about 500 sccm.

31. The method according to claim 19, wherein the process gas further comprises a dilution gas.

32. The method according to claim 31, wherein the dilution gas comprises Ar, He, Ne, Kr, Xe, or N₂, or a combination of two or more thereof.

33. The method according to claim 19, wherein the substrate comprises at least one of a semiconductor substrate, a LCD substrate, a glass substrate, or a combination of two or more thereof.

34. The method according to claim 19, wherein a thickness of the Ru metal layer is less than about 300 Å.

35. The method according to claim 19, wherein a thickness of the Ru metal layer is less than about 200 Å.

36. The method according to claim 19, wherein a thickness of the Ru metal layer is less than about 100 Å.

37. The method according to claim 19, wherein the patterned substrate further comprises a barrier layer and the depositing comprises depositing the Ru metal layer on the barrier layer

38. The method according to claim 37, wherein the barrier layer comprises W.
